(19) United States
(12) Patent Application Publication
(10) Pub. No.: US 2025/0351647 A1
(43) Pub. Date: Nov. 13, 2025

(54) DISPLAY DEVICE, METHOD OF MANUFACTURING THE SAME, AND ELECTRONIC DEVICE

(71) Applicant: Samsung Display Co., Ltd., Yongin-si (KR)

(72) Inventors: SANGWOOK HAN, Yongin-si (KR); INHYUK KIM, Yongin-si (KR); SANGHYUNG LIM, Yongin-si (KR); Hyeongsu Choi, Yongin-si (KR)

(21) Appl. No.: 19/174,706

(22) Filed: Apr. 9, 2025

(30) Foreign Application Priority Data
May 7, 2024 (KR) 10-2024-0059564

(51) Int. Cl. H10H 29/49; H10H 29/01; H10H 29/855

(52) U.S. Cl. CPC H10H 29/49; H10H 29/012; H10H 29/855

(57) ABSTRACT

A display device according to one or more embodiments may include a semiconductor circuit board including a pixel circuit, a bonding electrode above the semiconductor circuit board, and electrically connected to the pixel circuit, a pixel electrode above the bonding electrode, and electrically connected to the bonding electrode, a light-emitting element above the pixel electrode, a common electrode above the light-emitting element, and a capping layer above the common electrode, contacting the common electrode, and having an upper surface having a curved profile in a cross-sectional view.

### CROSS-REFERENCE TO RELATED APPLICATION(S)

The present application claims priority to, and the benefit of, Korean Patent Application No. 10-2024-0059564, filed on May 7, 2024, in the Korean Intellectual Property Office, the entire disclosure of which is incorporated herein by reference.

### BACKGROUND

### 1. Field

Embodiments relate to a high-resolution display device, a method of manufacturing the same, and an electronic device including the same.

### 2. Description of the Related Art

As the information society develops, the demand for a display device for displaying images has increased and diversified. The display device may include a flat panel display device, such as a liquid crystal display, a field emission display, or a light-emitting display. Light-emitting diodes included in the light-emitting display may include an organic light-emitting diode element, an inorganic semiconductor light-emitting element, a micro light-emitting diode element, or the like.

Recently, a head-mounted display (HMD) including the light-emitting display device has been developed. The head-mounted display is a glasses-type monitor device for virtual reality (VR) or augmented reality (AR) that is implemented in the form of glasses or a helmet to control a focus at a distance close to user's eyes in front of the user's eyes. A high-resolution micro light-emitting diode display device including a micro light-emitting diode element may be applied to the head-mounted display.

### SUMMARY

Embodiments provide a display device with improved display quality.

Embodiments also provide a method of manufacturing a display device with reduced manufacturing cost and time.

Embodiments also provide an electronic device including the display device.

Additional aspects of the embodiments will be set forth in the description which follows, and in part will be apparent from the description, or may be learned by practice of the embodiments.

A display device according to one or more embodiments may include a semiconductor circuit board including a pixel circuit, a bonding electrode above the semiconductor circuit board, and electrically connected to the pixel circuit, a pixel electrode above the bonding electrode, and electrically connected to the bonding electrode, a light-emitting element above the pixel electrode, a common electrode above the light-emitting element, and a capping layer above the common electrode, contacting the common electrode, and having an upper surface having a curved profile in a cross-sectional view.

The capping layer may include an inorganic insulating material.

The capping layer may have a substantially uniform thickness.

A profile of the upper surface of the capping layer may correspond to a profile of an upper surface of the common electrode.

The display device may further include a passivation layer covering a portion of an upper surface of the light-emitting element and a side surface of the light-emitting element, and defining an opening exposing another portion of the upper surface of the light-emitting element.

The common electrode may be above the passivation layer, and may contact the other portion of the upper surface of the light-emitting element through the opening.

The bonding electrode and the pixel electrode may have an island pattern shape, wherein the passivation layer is arranged along profiles of the bonding electrode, the pixel electrode, and the light-emitting element on the semiconductor circuit board.

A profile of an upper surface of the common electrode may correspond to a profile of an upper surface of the passivation layer.

A refractive index of the capping layer may be less than a refractive index of the light-emitting element.

A display device according to one or more embodiments may include a semiconductor circuit board including first and second pixel circuits, first and second bonding electrodes spaced apart above the semiconductor circuit board, and respectively electrically connected to the first and second pixel circuits, first and second pixel electrodes spaced apart, respectively above the first and second bonding electrodes, and respectively electrically connected to the first and second bonding electrodes, first and second light-emitting elements spaced apart and respectively above the first and second pixel electrodes, a common electrode above the first and second light-emitting elements, and a capping layer above the common electrode, contacting the common electrode, and having an upper surface that has a curved profile.

The capping layer may have a substantially uniform thickness.

The curved profile of the upper surface of the capping layer may correspond to a profile of an upper surface of the common electrode.

The first and second light-emitting elements may be configured to emit light of a same color.

A method of manufacturing a display device according to one or more embodiments may include bonding a first bonding electrode layer on a semiconductor circuit board including a pixel circuit to a second bonding electrode layer on a light-emitting stack including a light-emitting element substrate, a light-emitting element layer, and a pixel electrode layer, forming a first light-emitting element and a second light-emitting element that are spaced apart by removing the light-emitting element substrate, and by etching the light-emitting element layer, forming a common electrode on the first light-emitting element and the second light-emitting element, and forming, on the common electrode, a capping layer by depositing an inorganic insulating material using an atomic layer deposition method.

The capping layer may be formed to have a substantially uniform thickness.

A profile of an upper surface of the capping layer may correspond to a profile of an upper surface of the common electrode.

The method may further include forming a first pixel electrode and a second pixel electrode that are spaced apart by etching the pixel electrode layer.

The method may further include forming a first bonding electrode and a second bonding electrode that are spaced apart by etching a bonding electrode layer in which the first bonding electrode layer and the second bonding electrode layer are bonded.

The method may further include forming, on the first light-emitting element and the second light-emitting element, a passivation layer defining a first opening exposing a portion of an upper surface of the first light-emitting element, and defining a second opening exposing a portion of an upper surface of the second light-emitting element.

A refractive index of the inorganic insulating material may be less than a refractive index of the light-emitting element layer.

An electronic device according to one or more embodiments may include a display device and a power supply configured to provide power to the display device. The display device may include a semiconductor circuit board including a pixel circuit, a bonding electrode above the semiconductor circuit board, and electrically connected to the pixel circuit, a pixel electrode above the bonding electrode, and electrically connected to the bonding electrode, a light-emitting element above the pixel electrode, a common electrode above the light-emitting element, and a capping layer above the common electrode, contacting the common electrode, and having an upper surface having a curved profile in a cross-sectional view.

According to embodiments, the capping layer on the common electrode may function as a protective layer for protecting the common electrode, and may also function as a light-focusing layer for focusing light emitted from each of the light-emitting elements. Therefore, manufacturing cost and time of the display device may be reduced. In addition, even when a resolution of the display device increases, misalignment between convex portions of the capping layer and emission areas may not occur. Accordingly, a light emission efficiency of the display device may be further improved, and thus a display quality may be further improved.

It is to be understood that both the foregoing general description and the following detailed description are exemplary and explanatory and are intended to provide further explanation of the embodiments as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure, and together with the description serve to explain the present disclosure.

FIG. 1 is a plan view illustrating a display device according to one or more embodiments.

FIG. 2 is a cross-sectional view taken along the line I-I′ of FIG. 1.

FIG. 3 is an enlarged cross-sectional view illustrating an area A of FIG. 2.

FIGS. 4 to 11 are cross-sectional views illustrating a method of manufacturing a display device according to one or more embodiments.

FIG. 12 is a block diagram illustrating an electronic device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

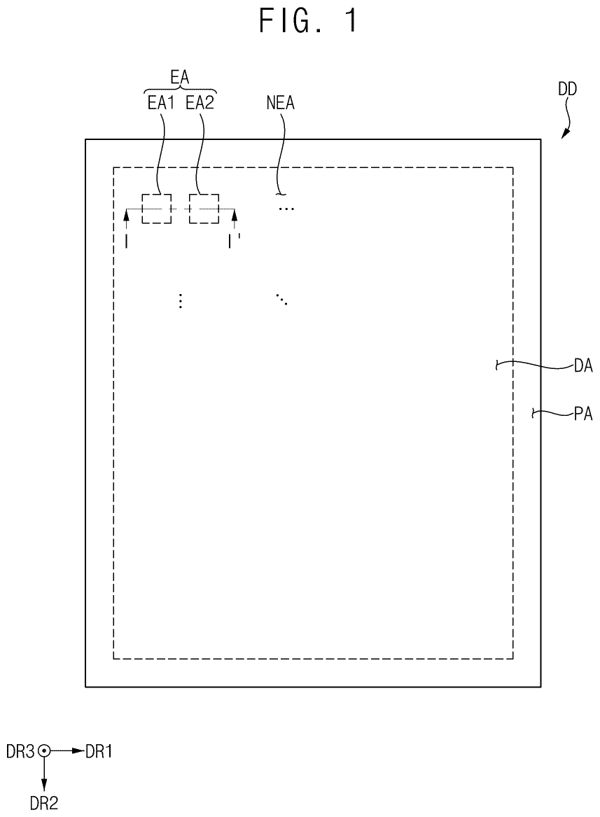

FIG. 1 is a plan view illustrating a display device according to one or more embodiments.

Referring to FIG. 1, a display device DD according to one or more embodiments may have a display surface defined by a first direction DR1, and by a second direction DR2 crossing the first direction DR1. The display device DD may display an image in a third direction DR3 through the display surface. For example, the second direction DR2 may be substantially perpendicular to the first direction DR1. The third direction DR3 may be substantially parallel to a normal direction of the display surface. The display surface may correspond to an upper surface (or a front surface) of the display device DD.

The display device DD may include a display area DA and a peripheral area PA. The image may be displayed in the display area DA. A plurality of pixels for generating the image may be located in the display area DA.

The display area DA may include a plurality of emission areas EA spaced apart from each other, and a non-emission area NEA between the emission areas EA. In a plan view, each of the emission areas EA may have an island pattern shape, and the emission areas EA may be spaced apart from each other. In one or more embodiments, the emission areas EA may be located in a matrix form along the first direction DR1 and the second direction DR2. The pixels for generating the image may be located in each of the emission areas EA. In a plan view, the non-emission area NEA may have a grid shape surrounding the emission areas EA.

Each of the pixels may include a pixel circuit and a light-emitting element. The pixel circuit may include at least one thin film transistor and at least one capacitor. The thin film transistor may generate a driving current, and may provide the generated driving current to the light-emitting element. The light-emitting element may emit light based on the driving current. The light emitted by each of the pixels may be combined to generate the image.

In one or more embodiments, all of the emission areas EA in the display area DA may emit light of the same color. In this case, the display device DD may display a single-color image. For example, each of the emission areas EA may emit blue light, but this is an example and embodiments are not limited thereto.

In one or more other embodiments, some of the emission areas EA in the display area DA may emit light of different colors. For example, the display area DA may include a red emission area that emits red light, a green emission area that emits green light, and a blue emission area that emits blue light. In this case, the display device DD may display a multi-color image. For example, the display device DD may include a color conversion layer, a color filter layer, or the like.

Hereinafter, for convenience of description, an example in which all of the emission areas EA in the display area DA emit light of the same color will be mainly described. For example, a first emission area EA1 and a second emission area EA2 illustrated in FIG. 1 may emit light of the same color (e.g., blue light).

The peripheral area PA may be located around the display area DA. The peripheral area PA may be located outside the display area DA. For example, the peripheral area PA may surround the display area DA in a plan view. A driver, such as a data driver and a gate driver, may be located in the peripheral area PA. The driver may provide various driving signals for driving the pixels, such as a driving voltage, a gate signal, a data signal, or the like, to the display area DA.

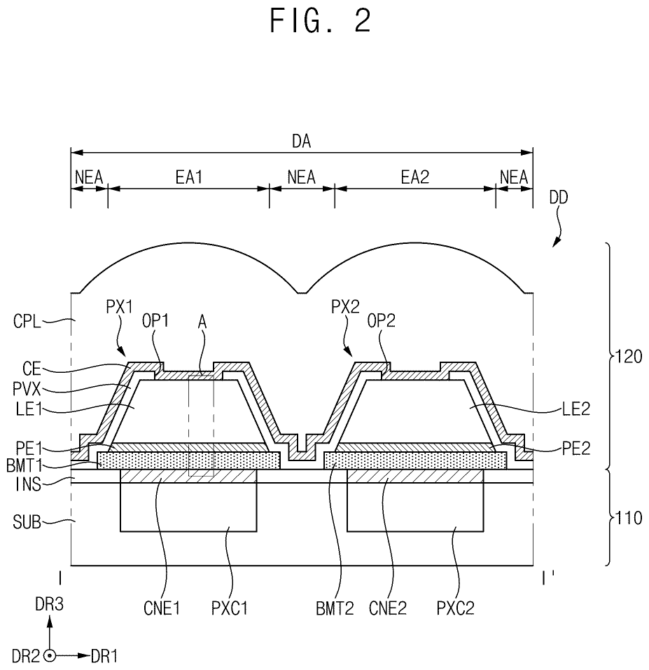

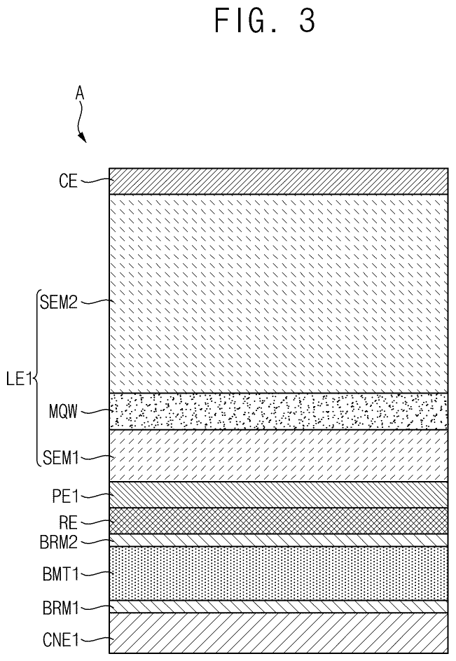

FIG. 2 is a cross-sectional view taken along the line I-I′ of FIG. 1. FIG. 3 is an enlarged cross-sectional view illustrating an area A of FIG. 2.

Referring to FIGS. 2 and 3, in one or more embodiments, the display device DD may include a semiconductor circuit board 110, bonding electrodes BMT1 and BMT2, and a display element layer 120. The display element layer 120 may be located on the semiconductor circuit board 110 (as used herein, “located on” may mean “above”). The display element layer 120 may be bonded to the semiconductor circuit board 110.

In one or more embodiments, the semiconductor circuit board 110 may include a substrate SUB, pixel circuits PXC1 and PXC2, an insulating layer INS, and connection electrodes CNE1 and CNE2. The display element layer 120 may include pixel electrodes PE1 and PE2, light-emitting elements LE1 and LE2, a passivation layer PVX, a common electrode CE, and a capping layer CPL.

In one or more embodiments, the substrate SUB may be a silicon wafer substrate. For example, the substrate SUB may include single crystal silicon.

Each of the pixel circuits PXC1 and PXC2 may be located on the substrate SUB. For example, each of the pixel circuits PXC1 and PXC2 may include a complementary metal-oxide semiconductor (CMOS) circuit formed by a semiconductor process. Each of the pixel circuits PXC1 and PXC2 may include at least one thin film transistor and at least one capacitor. For example, a first power voltage may be applied to each of the pixel circuits PXC1 and PXC2.

The first pixel circuit PXC1 may be electrically connected to the first light-emitting element LE1, and the second pixel circuit PXC2 may be electrically connected to the second light-emitting element LE2.

The connection electrodes CNE1 and CNE2 may be located on the substrate SUB. Each of the connection electrodes CNE1 and CNE2 may include a conductive material, such as a metal, an alloy, a conductive metal oxide, a conductive metal nitride, a transparent conductive oxide, or the like. Examples of the conductive material that may be used for each of the connection electrodes CNE1 and CNE2 may include copper (Cu), aluminum (Al), or alloys thereof. These may be used alone or in combination with each other. Each of the connection electrodes CNE1 and CNE2 may have a single-layer structure or a multi-layer structure including a plurality of conductive layers.

The first connection electrode CNE1 may be electrically connected to the first pixel circuit PXC1, and the second connection electrode CNE2 may be electrically connected to the second pixel circuit PXC2.

The insulating layer INS may be located on the substrate SUB and may insulate the first connection electrode CNE1 and the second connection electrode CNE2 from each other. The insulating layer INS may include an inorganic insulating material and/or an organic insulating material.

The bonding electrodes BMT1 and BMT2 may be located on the semiconductor circuit board 110. The bonding electrodes BMT1 and BMT2 may electrically connect the pixel circuits PXC1 and PXC2 to the corresponding pixel electrodes PE1 and PE2, respectively. In addition, the bonding electrodes BMT1 and BMT2 may bond the semiconductor circuit board 110 and the display element layer 120 to each other. Each of the bonding electrodes BMT1 and BMT2 may include a conductive material. Examples of the conductive material that may be used for each of the bonding electrodes BMT1 and BMT2 may include gold (Au), tin (Sn), Cu, Al, or alloys thereof. These may be used alone or in combination with each other. Each of the bonding electrodes BMT1 and BMT2 may have a single-layer structure or a multi-layer structure including a plurality of conductive layers.

The first bonding electrode BMT1 may be located in the first emission area EA1. The first bonding electrode BMT1 may be electrically connected to the first connection electrode CNE1.

The second bonding electrode BMT2 may be located in the second emission area EA2. The second bonding electrode BMT2 may be electrically connected to the second connection electrode CNE2.

In a plan view, each of the first bonding electrode BMT1 and the second bonding electrode BMT2 may have an island pattern shape, and the first bonding electrode BMT1 and the second bonding electrode BMT2 may be spaced apart from each other. The first bonding electrode BMT1 and the second bonding electrode BMT2 may be electrically insulated from each other.

The pixel electrodes PE1 and PE2 may be respectively located on the bonding electrodes BMT1 and BMT2. Each of the pixel electrodes PE1 and PE2 may include a conductive material. For example, each of the pixel electrodes PE1 and PE2 may include a transparent conductive oxide. Examples of the transparent conductive oxide that may be used for each of the pixel electrodes PE1 and PE2 may include indium tin oxide (ITO), indium zinc oxide (IZO), indium tin zinc oxide (ITZO), indium gallium oxide (IGO), indium gallium zinc oxide (IGZO), zinc oxide (ZnO), indium oxide (InO), tin oxide (SnO), gallium oxide (GaO), aluminum zinc oxide (AZO), or the like. These may be used alone or in combination with each other. However, embodiments are not limited thereto, and each of the pixel electrodes PE1 and PE2 may also include a metal, an alloy, a conductive metal nitride, or the like.

The first pixel electrode PE1 may be located in the first emission area EA1. The first pixel electrode PE1 may be electrically connected to the first bonding electrode BMT1. The first pixel electrode PE1 may be electrically connected to the first pixel circuit PXC1 through the first bonding electrode BMT1 and the first connection electrode CNE1.

The second pixel electrode PE2 may be located in the second emission area EA2. The second pixel electrode PE2 may be electrically connected to the second bonding electrode BMT2. The second pixel electrode PE2 may be electrically connected to the second pixel circuit PXC2 through the second bonding electrode BMT2 and the second connection electrode CNE2.

In a plan view, each of the first pixel electrode PE1 and the second pixel electrode PE2 may have an island pattern shape, and the first pixel electrode PE1 and the second pixel electrode PE2 may be spaced apart from each other. The first pixel electrode PE1 and the second pixel electrode PE2 may be electrically insulated from each other.

In one or more embodiments, as illustrated in FIG. 3, various conductive layers may be further located between the first connection electrode CNE1 and the first bonding electrode BMT1, and/or between the first bonding electrode BMT1 and the first pixel electrode PE1.

In one or more embodiments, a first barrier metal layer BRM1 may be located between the first connection electrode CNE1 and the first bonding electrode BMT1. For example, examples of conductive materials that may be used for the first barrier metal layer BRM1 may include titanium (Ti), molybdenum (Mo), or alloys thereof.

In one or more embodiments, a second barrier metal layer BRM2 and a reflective metal layer RE may be located between the first bonding electrode BMT1 and the first pixel electrode PE1. For example, the second barrier metal layer BRM2 may include the same material as the first barrier metal layer BRM1. The reflective metal layer RE may include a metal having relatively high reflectivity, such as Al. The reflective metal layer RE may reflect light emitted from the first light-emitting element LE1.

The light-emitting elements LE1 and LE2 may be respectively located on the pixel electrodes PE1 and PE2. The first light-emitting element LE1 may be located on the first pixel electrode PE1 in the first emission area EA1. The second light-emitting element LE2 may be located on the second pixel electrode PE2 in the second emission area EA2. In a plan view, each of the first light-emitting element LE1 and the second light-emitting element LE2 may have an island pattern shape, and the first light-emitting element LE1 and the second light-emitting element LE2 may be spaced apart from each other.

Each of the first and second light-emitting elements LE1 and LE2 may be a micro light-emitting diode or a nano light-emitting diode.

In one or more embodiments, as illustrated in FIG. 3, the first light-emitting element LE1 may include a first semiconductor layer SEM1, an active layer MQW, and a second semiconductor layer SEM2. The first semiconductor layer SEM1, the active layer MQW, and the second semiconductor layer SEM2 may be sequentially stacked in the third direction DR3.

The first semiconductor layer SEM1 may be located on the first pixel electrode PE1. The first semiconductor layer SEM1 may be a semiconductor layer doped with a first conductive dopant. The first conductive dopant may be a p-type dopant. Examples of the first conductive dopant may include magnesium (Mg), zinc (Zn), calcium (Ca), selenium (Se), barium (Ba), or the like. For example, the first semiconductor layer SEM1 may include p-GaN doped with p-type Mg, but embodiments are not limited thereto.

In one or more embodiments, an electron-blocking layer may be located on the first semiconductor layer SEM1. The electron-blocking layer may be a layer for suppressing or preventing too many electrons from flowing into the active layer MQW. For example, the electron-blocking layer may include p-AlGaN doped with p-type Mg, but embodiments are not limited thereto. The electron-blocking layer may be omitted.

The active layer MQW may be located on the first semiconductor layer SEM1. The active layer MQW may emit light by combining electron-hole pairs according to an electric signal applied through the first semiconductor layer SEM1 and the second semiconductor layer SEM2. For example, the active layer MQW may include InGaN, but embodiments are not limited thereto. A color of the emitted light may vary according to a content of indium included in the active layer MQW. For example, the active layer MQW may emit blue light, but embodiments are not limited thereto.

The active layer MQW may include a material having a single or multiple quantum well structure. When the active layer MQW includes a material having a multi quantum well structure, the active layer MQW may have a structure in which a plurality of well layers and barrier layers are alternately stacked.

In one or more embodiments, a superlattice layer may be located on the active layer MQW. The superlattice layer may be a layer for relieving stress between the active layer MQW and the second semiconductor layer SEM2. For example, the superlattice layer may include InGaN or GaN, but embodiments are not limited thereto. The superlattice layer may be omitted.

The second semiconductor layer SEM2 may be located on the active layer MQW. The second semiconductor layer SEM2 may be a semiconductor layer doped with a second conductive dopant. The second conductive dopant may be an n-type dopant. Examples of the second conductive dopant may include silicon (Si), germanium (Ge), Sn, or the like. For example, the second semiconductor layer SEM2 may include n-GaN doped with n-type Si, but embodiments are not limited thereto.

In one or more embodiments, the first and second light-emitting elements LE1 and LE2 may have substantially the same structure as each other. In one or more embodiments, the first and second light-emitting elements LE1 and LE2 may emit light of the same color. The active layer MQW of the first light-emitting element LE1 and an active layer of the second light-emitting element LE2 may include the same material as each other. For example, each of the first light-emitting element LE1 and the second light-emitting element LE2 may emit blue light, but embodiments are not limited thereto.

In one or more other embodiments, the first and second light-emitting elements LE1 and LE2 may emit light of different colors. For example, the active layer MQW of the first light-emitting element LE1 and the active layer of the second light-emitting element LE2 may include InGaN having different indium contents, but embodiments are not limited thereto.

The passivation layer PVX may be located on the first light-emitting element LE1 and the second light-emitting element LE2. In one or more embodiments, the passivation layer PVX may be entirely located on the display area DA.

The passivation layer PVX may cover the bonding electrodes BMT1 and BMT2, the pixel electrodes PE1 and PE2, and the light-emitting elements LE1 and LE2 on the semiconductor circuit board 110. The passivation layer PVX may cover an outer surface of each of the bonding electrodes BMT1 and BMT2, an outer surface of each of the pixel electrodes PE1 and PE2, an outer surface of each of the light-emitting elements LE1 and LE2, and a portion (e.g., a peripheral portion) of an upper surface of each of the light-emitting elements LE1 and LE2.

The passivation layer PVX may define openings OP1 and OP2 exposing a portion (e.g., a central portion) of the upper surface of each of the light-emitting elements LE1 and LE2.

The passivation layer PVX may define a first opening OP1 exposing a portion of an upper surface of the first light-emitting element LE1, and a second opening OP2 exposing a portion of an upper surface of the second light-emitting element LE2. The first opening OP1 and the second opening OP2 may be spaced apart from each other. The first opening OP1 may be located within the first emission area EA1, and the second opening OP2 may be located within the second emission area EA2.

In one or more embodiments, the passivation layer PVX may be located along profiles of the bonding electrodes BMT1 and BMT2, the pixel electrodes PE1 and PE2, and the light-emitting elements LE1 and LE2 on the semiconductor circuit board 110. As illustrated in FIG. 2, in a cross-sectional view, an upper surface of the passivation layer PVX may have a curved profile. In one or more embodiments, the passivation layer PVX may have a substantially uniform thickness.

In one or more embodiments, the passivation layer PVX may include an inorganic insulating material. Examples of inorganic insulating materials that may be used in the passivation layer PVX may include silicon oxide, silicon nitride, silicon oxynitride, or the like. These may be used alone or in combination with each other.

The common electrode CE may be located on the passivation layer PVX. In one or more embodiments, the common electrode CE may be entirely located on the display area DA.

The common electrode CE may have conductivity and light transmitting properties. Light emitted from the light-emitting elements LE1 and LE2 may pass through the common electrode CE, and may be emitted to the outside in the third direction DR3. In one or more embodiments, the common electrode CE may include a transparent conductive oxide, such as ITO, but embodiments are not limited thereto. For example, a second power voltage having a lower level than the first power voltage may be applied to the common electrode CE.

A portion of the common electrode CE may contact the portion of the upper surface of the first light-emitting element LE1 exposed by the first opening OP1 of the passivation layer PVX. The first pixel circuit PXC1, the first pixel electrode PE1, the first light-emitting element LE1, and the portion of the common electrode CE may constitute a first pixel PX1.

Another portion of the common electrode CE may contact the portion of the upper surface of the second light-emitting element LE2 exposed by the second opening OP2 of the passivation layer PVX. The second pixel circuit PXC2, the second pixel electrode PE2, the second light-emitting element LE2, and the another portion of the common electrode CE may constitute a second pixel PX2.

In one or more embodiments, the common electrode CE may be located along a profile of the passivation layer PVX. As illustrated in FIG. 2, in a cross-sectional view, an upper surface of the common electrode CE may have a curved profile. For example, the profile of the upper surface of the common electrode CE may correspond to the profile of the upper surface of the passivation layer PVX. In one or more embodiments, the common electrode CE may have a substantially uniform thickness.

The capping layer CPL may be located on the common electrode CE. In one or more embodiments, the capping layer CPL may be entirely located on the display area DA. The capping layer CPL may entirely cover the upper surface of the common electrode CE. The capping layer CPL may protect the common electrode CE.

The capping layer CPL may have a sufficient thickness to protect the common electrode CE. For example, the thickness of the capping layer CPL may be greater than each of a thickness of the common electrode CE and a thickness of the passivation layer PVX.

In one or more embodiments, the capping layer CPL may include an inorganic insulating material. In one or more embodiments, examples of inorganic insulating materials that may be used in the capping layer CPL may include silicon oxide, silicon nitride, silicon oxynitride, zirconium oxide, hafnium oxide, lanthanum oxide, tantalum oxide, yttrium oxide, niobium oxide, titanium oxide, aluminum nitride, zinc oxide, zinc sulfide, or the like. These may be used alone or in combination with each other.

A refractive index of the capping layer CPL may be less than a refractive index of each of the light-emitting elements LE1 and LE2. The refractive index of the capping layer CPL may be less than a refractive index of at least one of the first semiconductor layer SEM1, the active layer MQW, or the second semiconductor layer SEM2 of the first light-emitting element LE1. For example, the capping layer CPL may include a material having a refractive index less than that of GaN.

In one or more embodiments, the capping layer CPL may be located along a profile of the common electrode CE. As illustrated in FIG. 2, in a cross-sectional view, an upper surface of the capping layer CPL may have a curved profile. For example, the profile of the upper surface of the capping layer CPL may correspond to the profile of the upper surface of the passivation layer PVX. For example, the profile of the upper surface of the capping layer CPL may correspond to the profile of the upper surface of the common electrode CE. In one or more embodiments, the capping layer CPL may have a substantially uniform thickness.

In one or more embodiments, as illustrated in FIG. 2, a distance between a lower surface of the substrate SUB and the upper surface of the capping layer CPL in a central portion of each of the emission areas EA1 and EA2 may be greater than a distance between the lower surface of the substrate SUB and the upper surface of the capping layer CPL in the non-emission area NEA. For example, the distance between the lower surface of the substrate SUB and the upper surface of the capping layer CPL may gradually increase as it approaches the central portion of each of the emission areas EA1 and EA2.

In other words, the upper surface of the capping layer CPL may have a convexly curved profile in the third direction DR3 in an area overlapping each of the emission areas EA1 and EA2. For example, the capping layer CPL may have a shape in which convex portions each having a generally hemispherical shape are located to respectively overlap the emission areas EA1 and EA2. Accordingly, the capping layer CPL may focus (or collect) light emitted from each of the light-emitting elements LE1 and LE2 toward the third direction DR3. Therefore, a light emission efficiency of the display device DD may be improved, and thus a display quality of the display device DD may be improved.

A separate planarization layer having a flat upper surface may not be located on the common electrode CE. In one or more embodiments, the capping layer CPL may be directly located on the common electrode CE. The capping layer CPL may contact the upper surface of the common electrode CE. That is, another layer may not be located between the capping layer CPL and the common electrode CE, but embodiments are not limited thereto.

As described above, in a plan view, each of the light-emitting elements LE1 and LE2 may have an island pattern shape, and the light-emitting elements LE1 and LE2 may be spaced apart from each other. Each of the passivation layer PVX and the common electrode CE may be located along the profiles of the light-emitting elements LE1 and LE2. Accordingly, as illustrated in FIG. 2, a gap may be formed in the non-emission area NEA between the light-emitting elements LE1 and LE2 (or, between a portion, adjacent to the first light-emitting element LE1, of the upper surface of the common electrode CE and another portion, adjacent to the second light-emitting element LE2, of the upper surface of the common electrode CE).

In this case, when the capping layer CPL for protecting the common electrode CE is formed on the common electrode CE to have a substantially uniform thickness (or, to have relatively excellent step coverage), as illustrated in FIG. 2, the capping layer CPL may be formed such that the upper surface of the capping layer CPL has a convexly curved profile in the third direction DR3 in an area overlapping each of the emission areas EA1 and EA2. That is, the capping layer CPL may function as a protective layer for protecting the common electrode CE, and may also function as a light-focusing layer for focusing light emitted from each of the light-emitting elements LE1 and LE2. Therefore, compared to a comparative example in which a separate planarization layer is formed on the common electrode CE, and in which a separate light-focusing layer including a plurality of lenses is formed on the separate planarization layer, the manufacturing cost and time of the display device DD may be reduced.

In addition, in the comparative example in which the separate planarization layer and the separate light-focusing layer are formed on the common electrode CE, as the resolution increases, misalignment between the lenses included in the separate light-focusing layer and the emission areas EA1 and EA2 may occur, and thus the light emission efficiency may be reduced. However, according to embodiments, misalignment between the convex portions of the capping layer CPL and the emission areas EA1 and EA2 may not occur. Accordingly, the light emission efficiency of the display device DD may be further improved, and thus the display quality may be further improved.

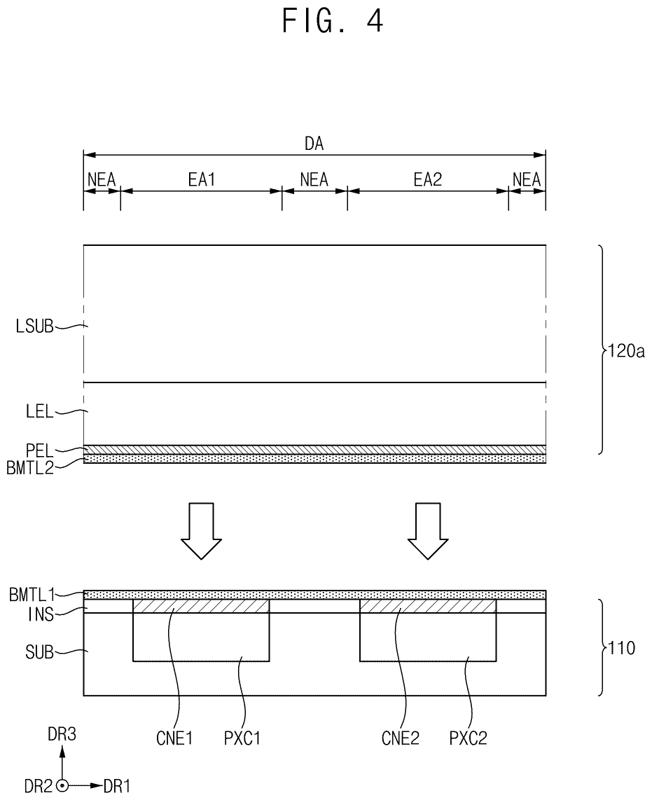

FIGS. 4 to 11 are cross-sectional views illustrating a method of manufacturing a display device according to one or more embodiments.

Hereinafter, an example of a method of manufacturing the display device DD of FIG. 2 will be described with reference to FIGS. 4 to 11, and repeated description will be omitted or simplified.

Referring to FIG. 4, first, the semiconductor circuit board 110 and a light-emitting stack 120a may be prepared.

The semiconductor circuit board 110 may include the substrate SUB, the pixel circuits PXC1 and PXC2, the insulating layer INS, and the connection electrodes CNE1 and CNE2.

The light-emitting stack 120a may include a light-emitting element substrate LSUB, a light-emitting element layer LEL, and a pixel electrode layer PEL. The light-emitting element substrate LSUB may be a silicon substrate or a sapphire substrate.

The light-emitting element layer LEL may be located on one surface of the light-emitting element substrate LSUB. The light-emitting element layer LEL may include the first semiconductor layer SEM1, the active layer MQW, and the second semiconductor layer SEM2 of FIG. 3. In this case, the second semiconductor layer SEM2, the active layer MQW, and the first semiconductor layer SEM1 may be sequentially staked on the one surface of the light-emitting element substrate LSUB.

The pixel electrode layer PEL may be located on one surface of the light-emitting element layer LEL to be opposite the light-emitting element substrate LSUB. For example, the pixel electrode layer PEL may include a transparent conductive oxide.

A first bonding electrode layer BMTL1 may be formed on one surface of the semiconductor circuit board 110. The first bonding electrode layer BMTL1 may be entirely formed on the one surface of the semiconductor circuit board 110.

A second bonding electrode layer BMTL2 may be formed on one surface of the light-emitting stack 120a. The second bonding electrode layer BMTL2 may be located on one surface of the pixel electrode layer PEL to opposite the light-emitting element layer LEL. The second bonding electrode layer BMTL2 may be entirely formed on the one surface of the pixel electrode layer PEL.

In one or more embodiments, the first bonding electrode layer BMTL1 and the second bonding electrode layer BMTL2 may include the same material as each other. For example, each of the first bonding electrode layer BMTL1 and the second bonding electrode layer BMTL2 may include at least one of Au, Sn, Cu, Al, or alloys thereof.

In one or more embodiments, the first barrier metal layer BRM1 of FIG. 3 may be further located between the semiconductor circuit board 110 and the first bonding electrode layer BMTL1, and the reflective metal layer RE and the second barrier metal layer BRM2 of FIG. 3 may be further located between the pixel electrode layer PEL and the second bonding electrode layer BMTL2.

Next, the semiconductor circuit board 110 and the light-emitting stack 120a may be bonded to each other using the first bonding electrode layer BMTL1 and the second bonding electrode layer BMTL2.

As illustrated in FIG. 4, the second bonding electrode layer BMTL2 formed on the one surface of the light-emitting stack 120a may be located to face the first bonding electrode layer BMTL1 formed on the one surface of the semiconductor circuit board 110.

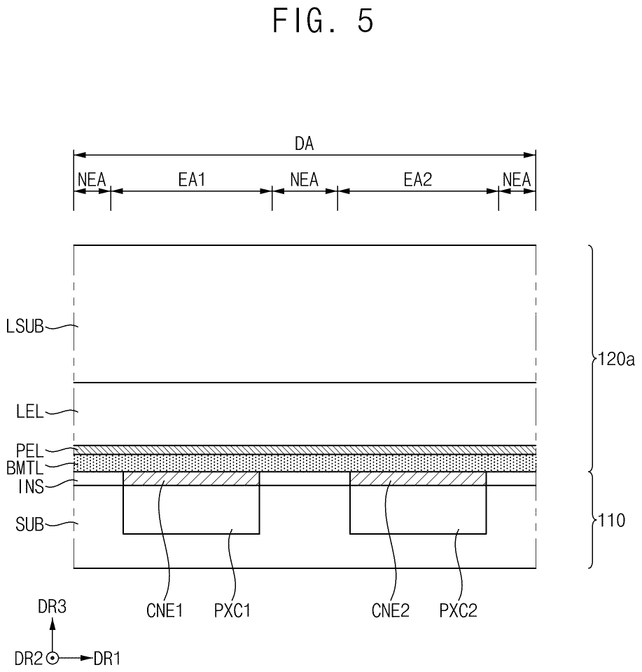

A bonding electrode layer BMTL of FIG. 5 may be formed by contacting the first bonding electrode layer BMTL1 and the second bonding electrode layer BMTL2, and by melt-bonding the first bonding electrode layer BMTL1 and the second bonding electrode layer BMTL2 at a corresponding temperature. As the first bonding electrode layer BMTL1 and the second bonding electrode layer BMTL2 are bonded to form the bonding electrode layer BMTL, the semiconductor circuit board 110 and the light-emitting stack 120a may be bonded to each other.

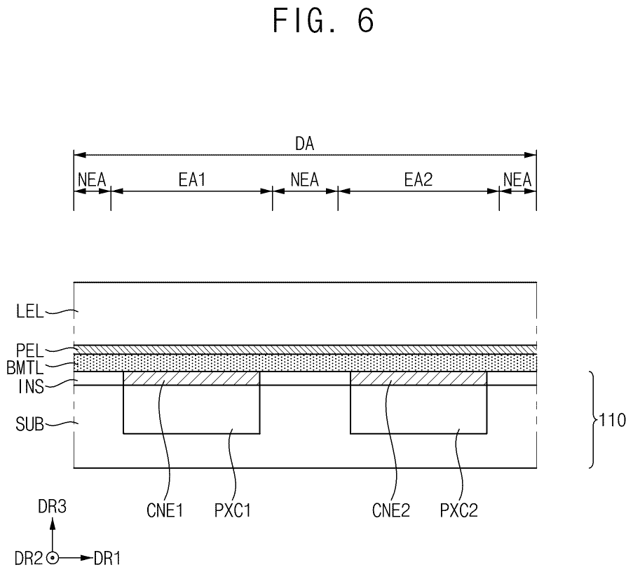

Next, as illustrated in FIG. 6, the light-emitting element substrate LSUB may be removed. In one or more embodiments, the light-emitting element substrate LSUB may be separated from the light-emitting element layer LEL by a laser lift-off process. In one or more other embodiments, the light-emitting element substrate LSUB may be removed by a polishing process, an etching process, or the like.

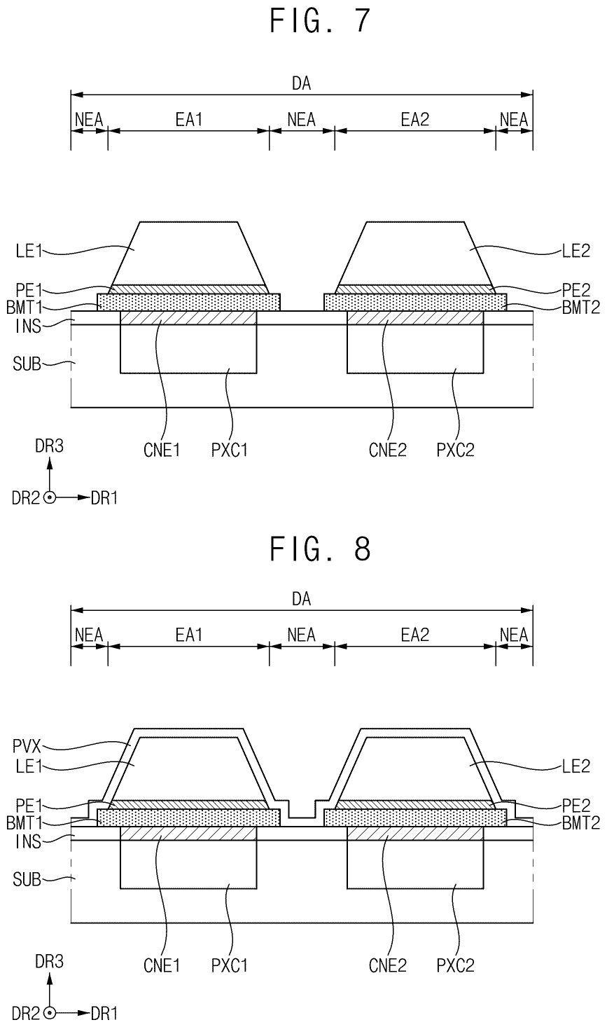

Next, as illustrated in FIG. 7, the first light-emitting element LE1 and the second light-emitting element LE2 spaced apart from each other may be formed by etching the light-emitting element layer LEL. For example, photoresist patterns may be formed on the light-emitting element layer LEL to respectively overlap the emission areas EA1 and EA2, and the light-emitting element layer LEL may be etched using the photoresist patterns as an etching mask.

The first pixel electrode PE1 and the second pixel electrode PE2 spaced apart from each other may be formed by etching the pixel electrode layer PEL, and the first bonding electrode BMT1 and the second bonding electrode BMT2 spaced apart from each other may be formed by etching the bonding electrode layer BMTL. The pixel electrode layer PEL and the bonding electrode layer BMTL may be etched concurrently or substantially simultaneously with, or after, etching the light-emitting element layer LEL.

Next, as illustrated in FIG. 8, the passivation layer PVX may be formed on the light-emitting elements LE1 and LE2. The passivation layer PVX may be entirely formed on the bonding electrodes BMT1 and BMT2, the pixel electrodes PE1 and PE2, and the light-emitting elements LE1 and LE2. The passivation layer PVX may be formed using an inorganic insulating material.

In one or more embodiments, the passivation layer PVX may be formed along profiles of the bonding electrodes BMT1 and BMT2, the pixel electrodes PE1 and PE2, and the light-emitting elements LE1 and LE2 on the semiconductor circuit board 110. As illustrated in FIG. 8, in a cross-sectional view, an upper surface of the passivation layer PVX may have a curved profile. In one or more embodiments, the passivation layer PVX may be formed to have a substantially uniform thickness.

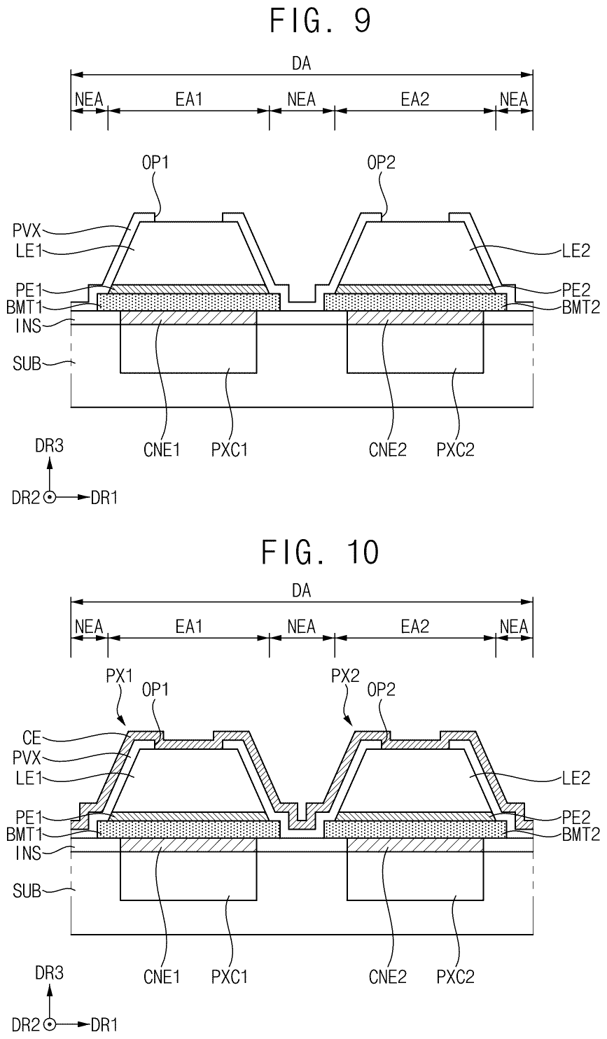

Next, as illustrated in FIG. 9, the first opening OP1 and the second opening OP2 may be formed by partially etching the passivation layer PVX. The first opening OP1 may be located within the first emission area EA1, and may expose a portion of an upper surface of the first light-emitting element LE1. The second opening OP2 may be located within the second emission area EA2, and may expose a portion of an upper surface of the second light-emitting element LE2.

Next, as illustrated in FIG. 10, the common electrode CE may be formed on the light-emitting elements LE1 and LE2 and the passivation layer PVX. The common electrode CE may be entirely formed on the passivation layer PVX. The common electrode CE may contact the portion of the upper surface of the first light-emitting element LE1 through the first opening OP1, and may contact the portion of the upper surface of the second light-emitting element LE2 through the second opening OP2. For example, the common electrode CE may be formed using a transparent conductive oxide, such as ITO.

In one or more embodiments, the common electrode CE may be formed along the profile of the passivation layer PVX. As illustrated in FIG. 10, in a cross-sectional view, an upper surface of the common electrode CE may have a curved profile. In one or more embodiments, the common electrode CE may be formed to have a substantially uniform thickness.

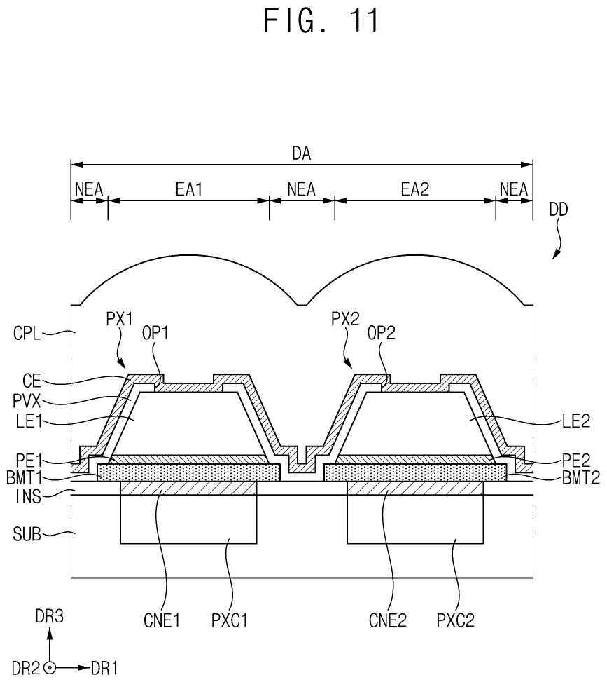

Next, as illustrated in FIG. 11, the capping layer CPL may be formed on the common electrode CE. The capping layer CPL may be entirely formed on the common electrode CE. The capping layer CPL may be formed using an inorganic insulating material. The inorganic insulating material may have a refractive index that is less than that of GaN.

In one or more embodiments, the capping layer CPL may be formed along the profile of the common electrode CE. As illustrated in FIG. 11, in a cross-sectional view, an upper surface of the capping layer CPL may have a curved profile. In one or more embodiments, the capping layer CPL may be formed to have a substantially uniform thickness (or, to have relatively excellent step coverage). For example, the capping layer CPL may be formed by depositing an inorganic insulating material using an atomic layer deposition (ALD) method.

According to embodiments, the capping layer CPL for protecting the common electrode CE may have a shape in which convex portions each having a generally hemispherical shape are located to respectively overlap the emission areas EA1 and EA2. Accordingly, the capping layer CPL may function as a protective layer for protecting the common electrode CE, and may also function as a light-focusing layer for focusing light emitted from each of the light-emitting elements LE1 and LE2. Therefore, compared to a comparative example in which a separate planarization layer is formed on the common electrode CE, and in which a separate light-focusing layer including a plurality of lenses is formed on the separate planarization layer, the manufacturing cost and time of the display device DD may be reduced. In addition, even when the resolution of the display device DD increases, misalignment between the convex portions of the capping layer CPL and the emission areas EA1 and EA2 may not occur. Accordingly, the light emission efficiency of the display device DD may be further improved, and thus the display quality may be further improved.

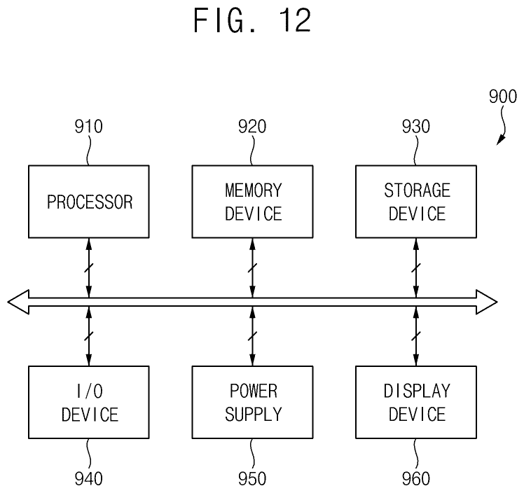

FIG. 12 is a block diagram illustrating an electronic device according to one or more embodiments.

Referring to FIG. 12, in one or more embodiments, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In one or more embodiments, the electronic device 900 may be implemented as a television. In one or more other embodiments, the electronic device 900 may be implemented as a smart phone. However, embodiments are not limited thereto, in one or more other embodiments, the electronic device 900 may be implemented as a cellular phone, a video phone, a smart pad, a smart watch, a tablet personal computer (“PC”), a car navigation system, a computer monitor, a laptop, a head located (e.g., mounted) display (“HMD”), or the like.

The processor 910 may perform various computing functions. In one or more embodiments, the processor 910 may be a microprocessor, a central processing unit (“CPU”), an application processor (“AP”), or the like. The processor 910 may be coupled to other components via an address bus, a control bus, a data bus, or the like. In one or more embodiments, the processor 910 may be coupled to an extended bus, such as a peripheral component interconnection (“PCI”) bus.

The memory device 920 may store data for operations of the electronic device 900. In one or more embodiments, the memory device 920 may include at least one non-volatile memory device, such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device, such as a dynamic random access memory (“DRAM”) device, a static random access memory (“SRAM”) device, a mobile DRAM device, or the like.

In one or more embodiments, the storage device 930 may include a solid state drive (“SSD”) device, a hard disk drive (“HDD”) device, a CD-ROM device, or the like. In one or more embodiments, the I/O device 940 may include an input device, such as a keyboard, a keypad, a mouse device, a touchpad, a touch-screen, or the like, and an output device, such as a printer, a speaker, or the like.

The power supply 950 may provide power for operations of the electronic device 900. The power supply 950 may provide power to the display device 960. The display device 960 may be coupled to other components via the buses or other communication links. In one or more embodiments, the display device 960 may be included in the I/O device 940.

Although embodiments and implementations have been described herein, other embodiments and modifications will be apparent from this description. Accordingly, the present disclosure is not limited to such embodiments, but rather to the broader scope of the appended claims and various obvious modifications and equivalent arrangements.

What is claimed is:

1. A display device comprising:
a semiconductor circuit board comprising a pixel circuit;
a bonding electrode above the semiconductor circuit board, and electrically connected to the pixel circuit;
a pixel electrode above the bonding electrode, and electrically connected to the bonding electrode;
a light-emitting element above the pixel electrode;
a common electrode above the light-emitting element; and
a capping layer above the common electrode, contacting the common electrode, and having an upper surface having a curved profile in a cross-sectional view.

2. The display device of claim 1, wherein the capping layer comprises an inorganic insulating material.

3. The display device of claim 1, wherein the capping layer has a substantially uniform thickness.

4. The display device of claim 1, wherein a profile of the upper surface of the capping layer corresponds to a profile of an upper surface of the common electrode.

5. The display device of claim 1, further comprising a passivation layer covering a portion of an upper surface of the light-emitting element and a side surface of the light-emitting element, and defining an opening exposing another portion of the upper surface of the light-emitting element.

6. The display device of claim 5, wherein the common electrode is above the passivation layer, and contacts the other portion of the upper surface of the light-emitting element through the opening.

7. The display device of claim 6, wherein the bonding electrode and the pixel electrode have an island pattern shape, and
wherein the passivation layer is arranged along profiles of the bonding electrode, the pixel electrode, and the light-emitting element on the semiconductor circuit board.

8. The display device of claim 7, wherein a profile of an upper surface of the common electrode corresponds to a profile of an upper surface of the passivation layer.

9. The display device of claim 1, wherein a refractive index of the capping layer is less than a refractive index of the light-emitting element.

10. A display device comprising:
a semiconductor circuit board comprising first and second pixel circuits;
first and second bonding electrodes spaced apart above the semiconductor circuit board, and respectively electrically connected to the first and second pixel circuits;
first and second pixel electrodes spaced apart, respectively above the first and second bonding electrodes, and respectively electrically connected to the first and second bonding electrodes;
first and second light-emitting elements spaced apart and respectively above the first and second pixel electrodes;
a common electrode above the first and second light-emitting elements; and
a capping layer above the common electrode, contacting the common electrode, and having an upper surface that has a curved profile.

11. The display device of claim 10, wherein the capping layer has a substantially uniform thickness.

12. The display device of claim 10, wherein the curved profile of the upper surface of the capping layer corresponds to a profile of an upper surface of the common electrode.

13. The display device of claim 10, wherein the first and second light-emitting elements are configured to emit light of a same color.

14. A method of manufacturing a display device, the method comprising:
bonding a first bonding electrode layer on a semiconductor circuit board comprising a pixel circuit to a second bonding electrode layer on a light-emitting stack comprising a light-emitting element substrate, a light-emitting element layer, and a pixel electrode layer;
forming a first light-emitting element and a second light-emitting element that are spaced apart by removing the light-emitting element substrate, and by etching the light-emitting element layer;
forming a common electrode on the first light-emitting element and the second light-emitting element; and
forming, on the common electrode, a capping layer by depositing an inorganic insulating material using an atomic layer deposition method.

15. The method of claim 14, the capping layer is formed to have a substantially uniform thickness.

16. The method of claim 14, wherein a profile of an upper surface of the capping layer corresponds to a profile of an upper surface of the common electrode.

17. The method of claim 14, further comprising forming a first pixel electrode and a second pixel electrode that are spaced apart by etching the pixel electrode layer.

18. The method of claim 14, further comprising forming a first bonding electrode and a second bonding electrode that are spaced apart by etching a bonding electrode layer in which the first bonding electrode layer and the second bonding electrode layer are bonded.

19. The method of claim 14, further comprising forming, on the first light-emitting element and the second light-emitting element, a passivation layer defining a first opening exposing a portion of an upper surface of the first light-emitting element, and defining a second opening exposing a portion of an upper surface of the second light-emitting element.

20. The method of claim 14, wherein a refractive index of the inorganic insulating material is less than a refractive index of the light-emitting element layer.

21. An electronic device comprising:
a display device; and
a power supply configured to provide power to the display device,
wherein the display device comprises:
a semiconductor circuit board comprising a pixel circuit;
a bonding electrode above the semiconductor circuit board, and electrically connected to the pixel circuit;
a pixel electrode above the bonding electrode, and electrically connected to the bonding electrode;
a light-emitting element above the pixel electrode;
a common electrode above the light-emitting element; and
a capping layer above the common electrode, contacting the common electrode, and having an upper surface having a curved profile in a cross-sectional view.
